(19) United States
(12) Patent Application Publication
(10) Pub. No.: US 2014/0117302 A1
(43) Pub. Date: May 1, 2014

(54) Phase Change Memory Cells, Methods Of Forming Phase Change Memory Cells, And Methods Of Forming Heater Material For Phase Change Memory Cells

(71) Applicant: MICRON TECHNOLOGY, INC., Boise, ID (US)

(72) Inventor: Jaydeb Goswami, Boise, ID (US)

(73) Assignee: MICRON TECHNOLOGY, INC., Boise, ID (US)

(21) Appl. No.: 13/666,744

(22) Filed: Nov. 1, 2012

(51) Int. Cl. H01L 45/00

(52) U.S. Cl. 257/4; 438/381; 257/E45.002

(57) ABSTRACT

A phase change memory cell includes a pair of electrodes having phase change material and heater material there-between. An electrically conductive thermal barrier material is between one of the electrodes and the heater material. Methods are disclosed.

### TECHNICAL FIELD

Embodiments disclosed herein pertain to phase change memory cells, to methods of forming phase change memory cells, and to methods of forming heater material for phase change memory cells.

### BACKGROUND

Memory is one type of integrated circuitry, and may be used in electronic systems for storing data. Memory is usually fabricated in one or more arrays of individual memory cells. The memory cells are configured to retain or store memory in at least two different selectable states. In a binary system, the states are considered as either a “0” or a “1”. In other systems, at least some individual memory cells may be configured to store more than two levels or states of information. The stored memory may be non-volatile wherein the memory state is maintained for a considerable period of time and in many instances where power is completely removed from the circuitry. Alternately, the memory may be volatile, requiring to be refreshed (i.e., rewritten), and in many instances multiple times per second.

One type of non-volatile memory is phase change memory. Such memories use a reversibly programmable material that has the property of switching between two different phases, for example between an amorphous, disorderly phase and a crystalline or polycrystalline, orderly phase. The two phases may be associated with resistivities of significantly different values. Presently, typical phase change materials are chalcogenides, although other materials may be developed. With chalcogenides, the resistivity may vary by two or more orders of magnitude when the material passes from the amorphous (more resistive) phase to the crystalline (more conductive) phase, and vice-versa. Phase change can be obtained by locally increasing the temperature of the chalcogenide. Below 150° C., both phases are stable. Starting from an amorphous state and rising to temperature above about 400° C., a rapid nucleation of the crystallites may occur and, if the material is kept at the crystallization temperature for a sufficiently long time, it undergoes a phase change to become crystalline. Reversion to the amorphous state can result by raising the temperature above the melting temperature (about 600° C.) followed by cooling.

In phase change memory, a plurality of memory cells is typically arranged in rows and columns to form an array or sub-array. Each memory cell is coupled to a respective select or access device which may be implemented by any switchable device, such as a PN diode, a bipolar junction transistor, a field effect transistor, etc. The access device is often electrically coupled with, or forms a part of, what is referred to as an access line or word line. A resistive electrode is electrically coupled with the switchable device, and comprises heater material which is configured to heat up upon sufficient current flowing there-through. The phase change material is provided in proximity to the heater material, thereby forming a programmable storage element. The crystallization temperature and the melting temperature are obtained by causing an electric current to flow through the heater material, thus heating the phase change material. An electrode, typically referred to as a bit, digit, or select line, is electrically coupled to the phase change material.

The temperature increase used to program phase change memory devices derives from current that is passed between the electrodes of the phase change memory cell. If current and/or voltage used to program such memory cells could be reduced, lower power consumption and/or other advantages may result.

### BRIEF DESCRIPTION OF THE DRAWINGS

FIG. 1 is a diagrammatic sectional view of a phase change memory cell in accordance with an embodiment of the invention.

FIG. 2 is a diagrammatic top plan view of an array of phase change memory cells in accordance with an embodiment of the invention.

FIG. 3 is a diagrammatic sectional view taken through line 3-3 in FIG. 2.

FIG. 4 is a diagrammatic sectional view taken through line 4-4 in FIG. 2.

FIG. 5 is a diagrammatic sectional view of a substrate fragment in process in accordance with an embodiment of the invention.

FIG. 6 is a view of the FIG. 5 substrate at a processing step subsequent to that shown by FIG. 5.

FIG. 7 is a view of the FIG. 6 substrate at a processing step subsequent to that shown by FIG. 6.

### DETAILED DESCRIPTION OF EXAMPLE EMBODIMENTS

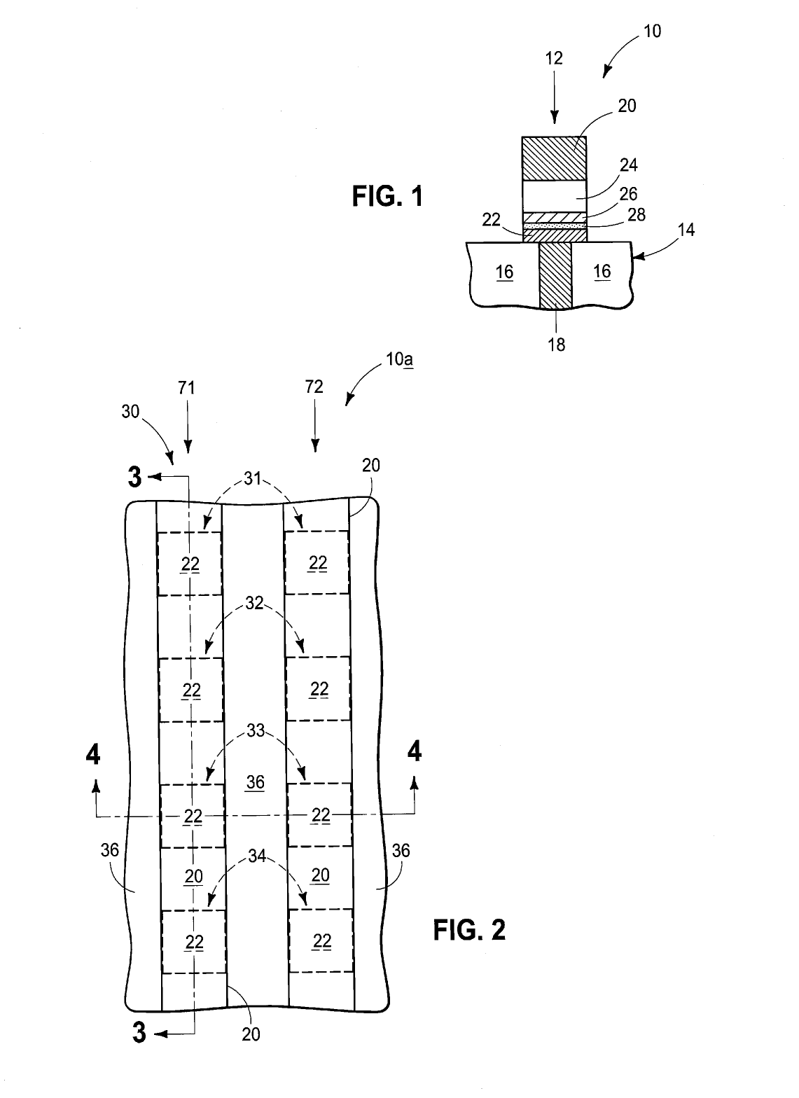

Embodiments of the invention include phase change memory cells, methods of forming phase change memory cells, and methods of forming heater material for phase change memory cells. Referring to FIG. 1, a substrate fragment 10 comprises an example phase change memory cell 12 in accordance with some embodiments of the invention. Substrate 10 may comprise a base substrate 14, which may comprise a semiconductor substrate. In the context of this document, the term “semiconductor substrate” or “semiconductive substrate” is defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above.

Base substrate 14 may be homogenous or non-homogenous, for example comprising multiple different composition materials and/or layers. As an example, base substrate 14 may comprise bulk monocrystalline silicon and/or a semiconductor-on-insulator substrate. Example base substrate 14 is shown as comprising dielectric material 16 and an electrically conductive material 18 extending there-through. Each may be homogenous or non-homogenous. As examples, dielectric material 16 may comprise silicon nitride, undoped silicon dioxide, and/or doped silicon dioxide. Electrically conductive material 18 may comprise any one or more electrically conductive materials, such as elemental metals, an alloy of two or more elemental metals, conductive metal compounds, and conductively doped semiconductor material (i.e., polysilicon). Electrically conductive material 18 may comprise or connect with a select device (not shown) for reading, writing, and erasing memory cell 12. Example select devices include diodes and transistors, although other existing or yet-to-be-developed devices may be used and which are not particularly material to inventive aspects disclosed herein.

Phase change memory cell 12 comprises a pair of electrically conductive electrodes 20 and 22 having phase change material 24 and heater material 26 there-between. An electrically conductive thermal barrier material 28 is between one of the electrodes (e.g., electrode 22) and heater material 26. Each of materials 20, 22, 24, 26, and 28 may be homogenous or non-homogenous. Suitable electrically conductive electrode materials 20, 22 include those described above for material 18. Electrode materials 20 and 22 may be of the same or different composition relative one another, and/or of the same or different composition relative to material 18.

By way of examples only, example phase change material 24 includes chalcogenides, such as GeSbTe-based materials. Example heater materials 26 include TiSiN-based materials and TiN-based materials having material other than silicon therein. Example electrically conductive thermal barrier materials 28 include carbon in combination with at least one of TaN, WN, Ta, W, Ru, Cu, Pt, Ir, and Al, including mixtures thereof. In one embodiment, the barrier material comprises carbon and nitrogen. In one embodiment, each of electrically conductive thermal barrier material 28 and heater material 26 comprises Ti and N, and in one embodiment also Si. In this document, an “electrically conductive” material refers to a material having compositional intrinsic electrical conductivity (i.e., electrical conductivity of at least about 10 siemens/meter at 20° C.) as opposed to electrical conductivity that could occur by movement of positive or negative charges through a thin material that is otherwise intrinsically dielectric. Further, “electrically conductive” and “electrical conductivity” is with respect to current flow predominantly by movement of subatomic positive and/or negative charges when such are generated as opposed to predominantly by movement of ions. Also, electrically conductive thermal barrier material in this document is characterized differently from electrode material in that it is of both lower electrical conductivity and lower thermal conductivity than the electrode material over which the electrically conductive thermal barrier material is received. Additionally, electrically conductive thermal barrier material in this document is characterized differently from heater material in that each is of different chemical composition relative the other. Further, a “thermal barrier material” in this document has specific (i.e., intrinsic) thermal resistance of at least 0.1 K·m/W.

In one embodiment, electrically conductive thermal barrier material 28 comprises carbon. In one embodiment, barrier material 28 and heater material 26 are of the same chemical composition but for quantity of carbon in the barrier material and quantity of carbon, if any, in the heater material. In one embodiment, the heater material comprises carbon, and in another embodiment the heater material is devoid of detectable carbon.

In one embodiment, barrier material 28 is less dense than heater material 26. In one embodiment, barrier material 28 has greater porosity than porosity, if any, in heater material 26. In one embodiment, heater material 26 is more electrically conductive than electrically conductive thermal barrier material 28. In one embodiment, heater material 26 is crystalline (i.e., at least 95% by volume crystalline) and barrier material 28 is amorphous (i.e., at least 95% by volume amorphous). In one embodiment, barrier material 28 has a minimum thickness which is less than that of heater material 26, in one embodiment a minimum thickness which is no greater than 25 Angstroms, and in one embodiment a minimum thickness of from 5 Angstroms to 20 Angstroms. An example minimum thickness for phase change material 24 is from 100 Angstroms to 500 Angstroms, while that for heater material 26 is from 10 Angstroms to 100 Angstroms.

In one embodiment, barrier material 28 is directly against heater material 26, and in one embodiment is directly against one of the pair of electrodes (e.g., electrode 22). In this document, a material or structure is “directly against” another when there is at least some physical touching contact of the stated materials or structures relative one another. In contrast, “over”, “on”, and “against” not preceded by “directly”, encompass “directly against” as well as construction where intervening material(s) or structure(s) result(s) in no physical touching contact of the stated materials or structures relative one another.

FIG. 1 depicts but one example embodiment of a phase change memory cell in accordance with the invention. Alternate existing or yet-to-be-developed constructions may be used, and embodiments of the invention encompass an array of phase change memory cells.

Additional embodiment phase change memory cells are next described with reference to FIGS. 2-4 with respect to a substrate fragment 10a. Like numerals from the above-described embodiments have been used where appropriate, with some construction differences being indicated with the suffix “a” or with different numerals. FIGS. 2-4 show an array 30 of phase change memory cells including phase change memory cells 31, 32, 33, and 34 in accordance with some embodiments of the invention. Memory cells 31-34 individually comprise a first electrode 22, an electrically conductive thermal barrier material 28a which is electrically coupled to first electrode 22, and a heater element 26a electrically coupled to first electrode 22 through electrically conductive thermal barrier material 28a. Materials and any other attribute may be as described above with respect to the example FIG. 1 embodiments. In one embodiment, heater element 26a and electrically conductive thermal barrier material 28a comprise overlapping angled plates 38 and 40, respectively. Angled plate 38 of heater material 26a has a first portion 42 and a second portion 46 that angles and extends elevationally outward from first portion 42. Angled plate 40 of barrier material 28a has a first portion 44 and a second portion 48 that angles and extends elevationally outward from first portion 44.

In one embodiment, first portions 42, 44 and second portions 46, 48 angle orthogonally relative one another. In one embodiment, first portions 42, 44 extend substantially horizontally (i.e., no more than plus or minus 5° from horizontal) and second portions 46, 48 extend substantially vertically (i.e., no more than plus or minus 5° from vertical). In this document, vertical is a direction generally orthogonal to a primary surface relative to which the substrate is processed during fabrication and which may be considered to define a generally horizontal direction. Further, “vertical” and “horizontal” as used herein are generally perpendicular directions relative one another independent of orientation of the substrate in three dimensional space. In one embodiment, angled plates 38, 40 are laterally and elevationally coextensive. In one embodiment, second portion 46 of heater material 26a has an outer edge 50 and second portion 48 of barrier material 28a has an outer edge 52. In one embodiment, outer edges 50 and 52 are each planar, and in one embodiment are co-planar.

Dielectric material 36 is received about heater elements 26a and electrically conductive thermal barrier material 28a. Such may be homogenous or non-homogenous, and examples include any of those described above for material 16. Dielectric material 36 may be of the same composition or of different composition relative to dielectric material 16. Phase change material 24 is over elevationally outer edges 50, 52 of each of second portions 46, 48, respectively, of heater element 26a and electrically conductive thermal barrier material 28a. A second electrode 20 is formed over phase change material 26. In the depicted embodiments, second electrodes 20 are in the form of lines 71, 72 (FIG. 2) which commonly connect a row/column of individual memory cells.

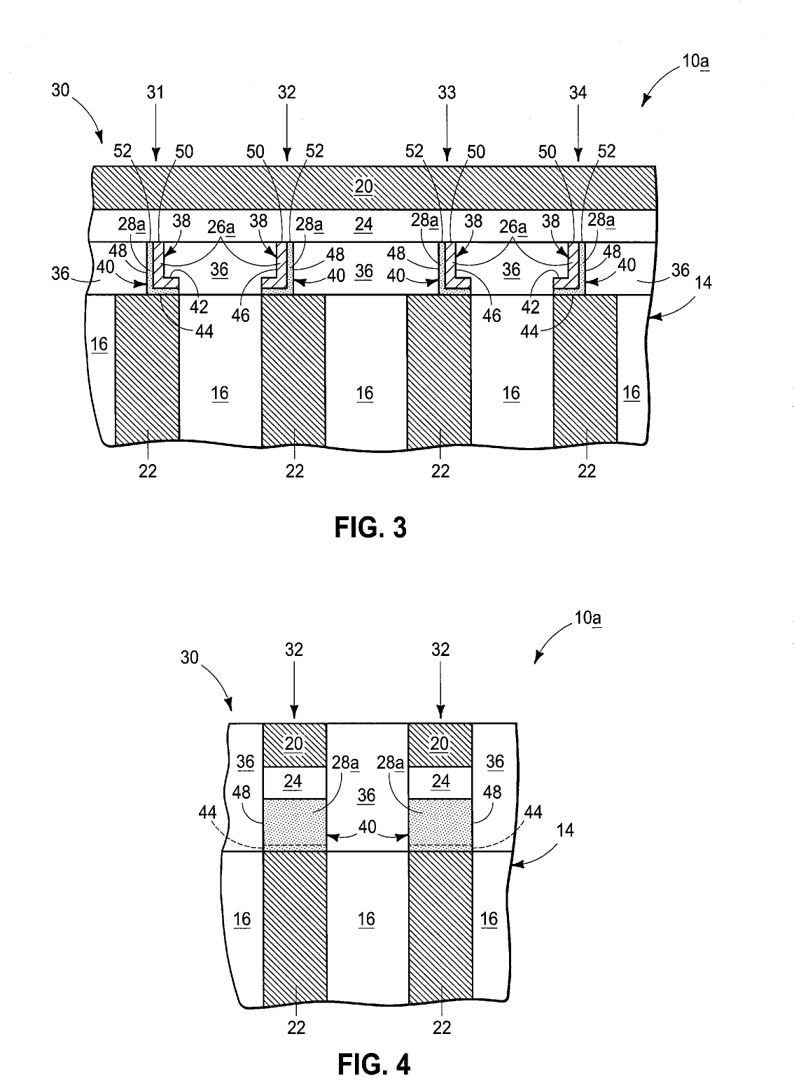

In one embodiment, the overlapped angled plates of immediately adjacent of the memory cells in the array are mirror images of one another. For example referring to FIG. 3, immediately adjacent memory cells 31/32, 32/33, and 33/34 have angled plates 38/40 which are mirror images of one another.

Embodiments of the invention encompass a method of forming a phase change memory cell which includes forming an electrically conductive thermal barrier material over a first electrode of the memory cell. Material composition and attributes include any of those described above for electrode 22 and for thermal barrier material 28/28a. Heater material is formed over the electrically conductive thermal barrier material, and may include any of the composition and any other attribute described above for heater material 26/26a. Phase change material is formed over the heater material, and may include any of the composition and any other attribute described above with respect to phase change material 24. A second electrode of the memory cell is formed over the phase change material, and may include any of the composition and any other attribute described above with respect to second electrode 20.

The stated materials may be formed, for example, by deposition methods including any of physical vapor deposition, chemical vapor deposition, and/or atomic layer deposition, and with or without plasma. In one embodiment, forming of the electrically conductive thermal barrier material and forming of the heater material comprise using at least one deposition precursor which is common to the stated acts of forming the barrier material and of the heater material. In one embodiment, the forming of the barrier material and the forming of the heater material occur in situ in the same deposition chamber.

Embodiments of the invention include methods of forming heater material for a phase change memory cell. In one embodiment, an electrically conductive thermal barrier material is deposited over an electrode of a phase change memory cell that is being fabricated. Crystalline heater material (i.e., at least 95% by volume crystalline) is deposited directly against the electrically conductive thermal barrier material. The electrically conductive thermal barrier material is amorphous (i.e., at least 95% by volume amorphous) and of lower density than the crystalline heater material. Composition and any other attribute as described above for the thermal barrier material and the heater material may be used. In one embodiment, a deposition precursor is used in each of the acts of depositing the thermal barrier material and the crystalline heater material that is the same deposition precursor. In one embodiment, only that same deposition precursor is used in the depositing of the barrier material, and the same and another deposition precursor are used in depositing of the heater material.

In one embodiment, a method of forming heater material for a phase change memory cell comprises using at least one of a metalorganic precursor and an organometallic precursor in depositing electrically conductive thermal barrier material over an electrode of a phase change memory cell that is being fabricated. The same at least one metalorganic precursor and/or organometallic precursor is used in depositing heater material directly against the electrically conductive thermal barrier material. The heater material is of higher electrical conductivity and higher thermal conductivity than the electrically conductive thermal barrier material. The electrically conductive thermal barrier material has higher carbon content than any carbon content, if any, in the heater material. Composition and any other attribute for the electrically conductive thermal barrier material and the heater material may be as described above. In one embodiment, at least some of the carbon from the barrier material is removed prior to depositing the heater material, for example by exposure to hydrogen and/or nitrogen-containing plasma.

In some embodiments, deposition of the heater material occurs by chemical vapor deposition and/or atomic layer deposition with or without remote and/or in situ plasma. Example flow rates of individual precursors include from 5 mg/min to 200 mg/min. Example chamber pressure during deposition is anywhere from 1 mTorr to 760 Torr, with 5 Torr being a specific example. Example temperatures of the support upon which the substrate rests during deposition is from 200° C. to 600° C. In some embodiments, a single metalorganic or organometallic deposition precursor having all of the components of the electrically conductive thermal barrier material is provided to the deposition chamber whereupon thermal decomposition thereof occurs in depositing the electrically conductive thermal barrier material on the substrate. Such barrier material will likely contain carbon, with some or all of such perhaps being removed from the barrier material prior to forming heater material there-over. Example precursors, depending upon composition of the electrically conductive thermal barrier material, include tetradimethylamino titanium, tetradiethylamino titanium, tetraethylmethylamino titanium, tert-butyldimethylamino titanium, tetradimethyl-amino tantalum, tetradiethylamino tantalum, tetraethylmethylamino tantalum tert-butyldimethylamino tantalum, tungsten hexa-carbonyl, 1,5-cyclooctadiene iridium, methylcyclopentadienyl platinum, ruthenium(III)acetylacetonate, triruthenium-dodecacarbonyl, bis(eta(5)-cyclopentadienyl) ruthenium, bis(ethylcyclopentadienyl) ruthenium, tris(dipivaloylmethanate) ruthenium, copper(II)acetylacetonate, copper(II) trifluoroacetylacetonate, and trimethylaluminum. In one embodiment, processing may continue with in situ deposition of the heater material over the barrier material by the addition of one or more precursors which may be reactive and which may include additional components therein portions of which become one or more additional components in the heater material.

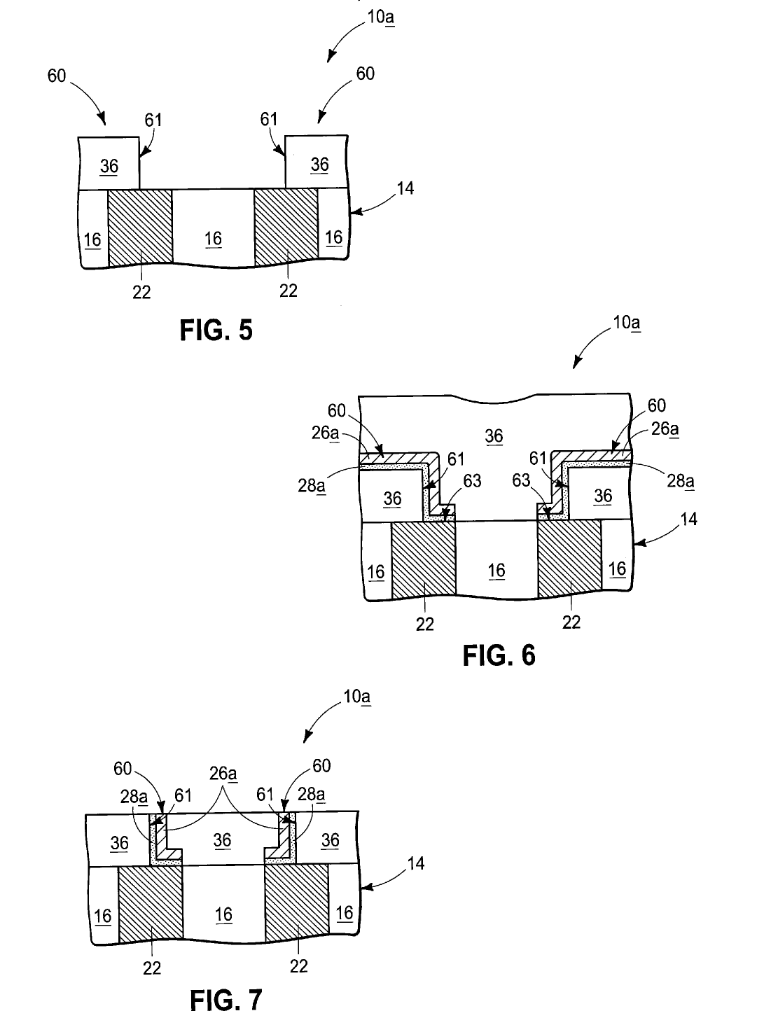

An embodiment of a method of forming a phase change memory cell in accordance with an aspect of the invention is described with reference to FIGS. 5-7. Such may be used, for example, in fabricating the structure of the FIGS. 2-4 embodiment. FIG. 5 depicts a portion of a predecessor substrate 10a to the more completed construction of the substrate of FIG. 3. The discussion proceeds with respect to fabrication of a single phase change memory cell, although it will be recognized that multiple such phase change memory cells may and likely will be fabricated (e.g., thousands or millions may be fabricated, with two memory cells being shown in FIGS. 5-7). Referring to FIG. 5, a structure 60 has been formed elevationally over a first electrode 22 of the memory cell that is being fabricated. Structure 60 is shown by way of example as being comprised of dielectric material 36 which has a sidewall 61 that is elevationally over first electrode 22. Composition and any other attribute may be as described above.

Referring to FIG. 6, an electrically conductive thermal barrier material 28a has been formed laterally over structure sidewall 61 and to extend laterally of structure 60 across an elevationally upper surface 63 of first electrode 22. Heater material 26a has been formed over electrically conductive thermal barrier material 28a, with heater material 26a thereby also being laterally over structure sidewall 61 and extending laterally of structure 60 across elevationally upper surface 63 of first electrode 22. Barrier material 28a and heater material 26a have been patterned, for example to separate facing memory cells and not necessarily to terminate at the lateral edges of first electrodes 22. Then, sidewall portions of heater material 26a and portions of heater material 26a that extend laterally of structure 60 across elevationally upper surface 63 of first electrode 22 are covered, for example with dielectric material 36 in the depicted embodiment. Alternate patterning techniques may be used prior to covering with material 36. By way of example only, materials 28a and 26a may be patterned using a maskless anisotropic spacer etch process (not shown) whereby materials 26a and 28a are removed from being over horizontal surfaces but for at least some of the horizontal surfaces of first electrodes 22 (and with or without prior deposition of an additional spacer layer before the etch).

Alternately as another example, barrier material 28a and heater material 26a might not be patterned prior to being covered with material 36.

Referring to FIG. 7, dielectric material 36, electrically conductive thermal barrier material 28a, and heater material 26a have been planarized back at least to the horizontal surfaces of the inner portions of material 36 beneath materials 28a and 26a. Alternately, materials 28a and 26a may have been previously removed from horizontal surfaces of the inner portions of material 36 if spacer-like processing as described above was used (or if other previous patterning occurred).

Subsequent processing may occur to produce a construction like that of FIG. 3. For example, phase change material 24 may be formed across an elevationally outermost surface 52 of electrically conductive thermal barrier material 28a and across an elevationally outermost surface 50 of heater material 26a. A second electrode 20 of the memory cell being fabricated may be formed over phase change material 24. Composition and any other attribute as described above may be used.

Use of an electrically conductive thermal barrier material between the heater material and one of the electrodes in a phase change memory cell may eliminate or at least reduce heat loss through that electrode. This may reduce overall applied voltage and/or current to the heater material that is necessary to implement the reversible phase changes, and may thereby reduce power consumption or provide other operational advantages in a phase change memory cell. Such may further, by way of example only, reduce bit error rate failures, and perhaps increase product yield.

### Conclusion

In some embodiments, a phase change memory cell comprises a pair of electrodes having phase change material and heater material there-between. An electrically conductive thermal barrier material is between one of the electrodes and the heater material.

In some embodiments, a phase change memory cell comprises a first electrode and an electrically conductive thermal barrier material electrically coupled to the first electrode. A heater element is electrically coupled to the first electrode through the electrically conductive thermal barrier material. The heater element and the electrically conductive thermal barrier material comprise overlapping angled plates respectively having a first portion and a second portion that angles and extends elevationally outward from the first portion. Phase change material is over an elevationally outer edge of each of the second portions of the electrically conductive thermal barrier material and the heater element. A second electrode is over the phase change material.

In some embodiments, a method of forming a phase change memory cell comprises forming an electrically conductive thermal barrier material over a first electrode of the memory cell. Heater material is formed over the electrically conductive thermal barrier material. Phase change material is formed over the heater material. A second electrode of the memory cell is formed over the phase change material.

In some embodiments, a method of forming a phase change memory cell comprises forming a structure elevationally over a first electrode of the memory cell that is being fabricated. The structure comprises a sidewall that is elevationally over the first electrode. An electrically conductive thermal barrier material is formed laterally over the structure sidewall and to extend laterally of the structure across an elevationally upper surface of the first electrode. Heater material is formed over the electrically conductive thermal barrier material. The heater material is laterally over the structure sidewall and extends laterally of the structure across the elevationally upper surface of the first electrode. Sidewall portions of the heater material are covered and portions of the heater material that extends laterally of the structure across the elevationally upper surface of the first electrode are covered. Phase change material is formed across an elevationally outermost surface of the electrically conductive thermal barrier material and across an elevationally outermost surface of the heater material. A second electrode of the memory cell that is being fabricated is formed over the phase change material.

In some embodiments, a method of forming heater material for a phase change memory cell comprises depositing an electrically conductive thermal barrier material over an electrode of a phase change memory cell that is being fabricated. Crystalline heater material is formed directly against the electrically conductive thermal barrier material. The electrically conductive thermal barrier material is amorphous and of lower density than the crystalline heater material.

In some embodiments, a method of forming heater material for a phase change memory cell comprises using at least one of a metalorganic precursor and an organometallic precursor in depositing electrically conductive thermal barrier material over an electrode of a phase change memory cell that is being fabricated. The same at least one metalorganic precursor and/or organometallic precursor is used in depositing heater material directly against the electrically conductive thermal barrier material. The heater material is of higher electrical conductivity and higher thermal conductivity than the electrically conductive thermal barrier material. The electrically conductive thermal barrier material has higher carbon content than any carbon content, if any, in the heater material.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A phase change memory cell comprising a pair of electrodes having phase change material and heater material there-between, an electrically conductive thermal barrier material between one of the electrodes and the heater material.

2. The memory cell of claim 1 wherein the barrier material has a minimum thickness which is less than that of the heater material.

3. The memory cell of claim 2 wherein the minimum thickness of the barrier material is no greater than 25 Angstroms.

4. The memory cell of claim 1 wherein the barrier material is less dense than the heater material.

5. The memory cell of claim 1 wherein the barrier material has greater porosity than porosity, if any, in the heater material.

6. The memory cell of claim 1 wherein the heater material is crystalline and the barrier material is amorphous.

7. The memory cell of claim 1 wherein the heater material is more electrically conductive than the electrically conductive thermal barrier material.

8. The memory cell of claim 1 wherein the barrier material and the heater material are of the same chemical composition but for quantity of carbon in the barrier material and quantity of carbon, if any, in the heater material.

9. The memory cell of claim 8 wherein the heater material comprises carbon.

10. The memory cell of claim 8 wherein the heater material is devoid of detectable carbon.

11. The memory cell of claim 1 wherein each of the barrier material and the heater material comprises Ti and N.

12. The memory cell of claim 11 wherein each of the barrier material and the heater material comprises Si.

13. The method of claim 1 wherein the barrier material comprises carbon and nitrogen

14. The memory cell of claim 1 wherein the barrier material comprises carbon and at least one of Ta, W, Ru, Cu, Pt, Ir, and Al, including mixtures thereof.

15. The memory cell of claim 1 wherein the barrier material is directly against the heater material.

16. The memory cell of claim 1 wherein the barrier material is directly against the one electrode.

17. A phase change memory cell comprising:
a first electrode;
an electrically conductive thermal barrier material electrically coupled to the first electrode;
a heater element electrically coupled to the first electrode through the electrically conductive thermal barrier material, the heater element and the electrically conductive thermal barrier material comprising overlapping angled plates respectively having a first portion and a second portion that angles and extends elevationally outward from the first portion;
phase change material over an elevationally outer edge of each of the second portions of the electrically conductive thermal barrier material and the heater element; and
a second electrode over the phase change material.

18. The memory cell of claim 17 wherein the first and second portions angle orthogonally relative one another.

19. The memory cell of claim 17 wherein the second portion extends substantially vertically.

20. The memory cell of claim 17 wherein the first portion extends substantially horizontally.

21. The memory cell of claim 17 wherein the angled plates of the heater element and the barrier material are laterally and elevationally coextensive.

22. The memory cell of claim 17 wherein the outer edge of each of the second portions of the barrier material and the heater element is planar.

23. The memory cell of claim 22 wherein the outer edges are coplanar.

24. An array of said phase change memory cells of claim 17 wherein the overlapped angled plates of immediately adjacent of the memory cells in the array are mirror images of one another.

25. A method of forming a phase change memory cell, comprising:
forming an electrically conductive thermal barrier material over a first electrode of the memory cell;
forming heater material over the electrically conductive thermal barrier material;
forming phase change material over the heater material; and
forming a second electrode of the memory cell over the phase change material.

26. The method of claim 25 wherein forming electrically conductive thermal barrier material comprises using at least one deposition precursor and forming the heater material comprises using at least one deposition precursor, the forming of the barrier material and the forming of the heater material using at least one common deposition precursor.

27. The method of claim 25 wherein the forming of the barrier material and the forming of the heater material occurs in situ in the same deposition chamber.

28. A method of forming a phase change memory cell, comprising:
forming a structure elevationally over a first electrode of the memory cell that is being fabricated, the structure comprising a sidewall that is elevationally over the first electrode;
forming an electrically conductive thermal barrier material laterally over the structure sidewall and to extend laterally of the structure across an elevationally upper surface of the first electrode;
forming heater material over the electrically conductive thermal barrier material, the heater material being laterally over the structure sidewall and extending laterally of the structure across the elevationally upper surface of the first electrode;
covering sidewall portions of the heater material and covering portions of the heater material that extends laterally of the structure across the elevationally upper surface of the first electrode;
forming phase change material across an elevationally outermost surface of the electrically conductive thermal barrier material and across an elevationally outermost surface of the heater material; and
forming a second electrode of the memory cell that is being fabricated over the phase change material.

29. The method of claim 28 comprising forming the phase change material directly against the thermal barrier material and directly against the heater material.

30. A method of forming heater material for a phase change memory cell, comprising:
depositing an electrically conductive thermal barrier material over an electrode of a phase change memory cell that is being fabricated; and
depositing crystalline heater material directly against the electrically conductive thermal barrier material, the electrically conductive thermal barrier material being amorphous and of lower density than the crystalline heater material.

31. The method of claim 30 comprising using a deposition precursor in each of the depositings that is the same deposition precursor.

32. The method of claim 31 wherein only the same deposition precursor is used in the depositing of the barrier material, and using the same and another deposition precursor in the depositing of the heater material.

33. A method of forming heater material for a phase change memory cell, comprising:
using at least one of a metalorganic precursor and an organometallic precursor in depositing electrically conductive thermal barrier material over an electrode of a phase change memory cell that is being fabricated; and
using the same at least one metalorganic precursor and/or organometallic precursor in depositing heater material directly against the electrically conductive thermal barrier material, the heater material being of higher electrical conductivity and higher thermal conductivity than the electrically conductive thermal barrier material, the electrically conductive thermal barrier material having higher carbon content than any carbon content, if any, in the heater material.

34. The method of claim 33 comprising removing at least some of the carbon from the barrier material prior to depositing the heater material.
